(19) United States
(12) Patent Application Publication
(10) Pub. No.: US 2015/0285859 A1
(43) Pub. Date: Oct. 8, 2015

(54) INTEGRATED CIRCUIT WITH LBIST SUB-PARTITIONS

(71) Applicants: Reecha Jajodia, Noida (IN); Gagan Anand, Gohana (IN); Anurag Jindal, Patiala (IN)

(72) Inventors: Reecha Jajodia, Noida (IN); Gagan Anand, Gohana (IN); Anurag Jindal, Patiala (IN)

(73) Assignee: Freescale Semiconductor, Inc., Austin, TX (US)

(21) Appl. No.: 14/246,131

(22) Filed: Apr. 6, 2014

(51) Int. Cl. G01R 31/3177

(52) U.S. Cl. CPC G01R 31/3177

(57) ABSTRACT

A Logic Built-In Self-Test (LBIST) domain of an integrated circuit is divided into partitions that in turn are subdivided into sub-partitions. Each sub-partition has an associated clock gating logic circuit that enables or inhibits the clock signal supplied to scan chains within the sub-partition. A user-defined number of sub-partitions, which can be specified on the basis of silicon results and power requirements of the integrated circuit, may be activated at any one time during a portion of an LBIST execution, which reduces toggling of concurrent scan chains, resulting in a reduction of energy consumption during testing, and reduces voltage droop due to inertia of power management control modules at the start of an LBIST test.

### BACKGROUND OF THE INVENTION

The present invention relates generally to integrated circuits and, more particularly, to an integrated circuit including Logic Built-In Self Test (LBIST) partitions.

Integrated circuit devices, such as microprocessors or system-on-chip (SOC) devices typically include a complex matrix of logic gates arranged to perform particular functions. These logic gates are often interconnected in two parallel arrangements, one arrangement for operation, and another arrangement for testing. Linking a plurality of latches together into a “scan chain” is one known method of arranging logic units for testing. Such scan chains may be used to gain access to internal nodes of the integrated circuit. Test patterns are shifted in by the scan chains and functional clock signals are pulsed to test the circuit during a capture cycle. The results are then shifted out to output pins and compared against expected results.

One known method for generating test data for application to the scan chains is LBIST (Logic Built-In Self-Test), which is widely used to detect certain manufacturing defects. LBIST is also a useful tool for studying hardware power and frequency characteristics. However, the electrical power generated during a full-chip LBIST scan can become unreasonably high, sometimes exceeding tolerable levels. High peak and average power dissipation is usually attributable to a high random switching activity due to a high level of toggling inherent in the LBIST design.

Another problem that is often encountered during LBIST execution, particularly at start-up, is the large power droop due to slow frequency response of the power management controllers associated with the LBIST system. Thus it would be advantageous to provide a BIST arrangement system that addresses the simultaneous switching and power droop issues.

### BRIEF DESCRIPTION OF THE DRAWINGS

The invention, together with objects and advantages thereof, may best be understood by reference to the following description of preferred embodiments together with the accompanying drawings in which:

FIG. 1 is a simplified schematic block diagram of a portion of an integrated circuit including an LBIST domain.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides an integrated circuit having at least one LBIST partition with a plurality of sub-partitions. A controller is coupled to the LBIST partition and provides control signals for each sub-partition. A power management module is coupled to the controller and generates a clock enable/inhibit signal to enable clock signals provided to selected ones of the sub-partitions.

In another embodiment, the present invention provides a method for LBIST in an LBIST partition. The method includes dividing a partition into a plurality of sub-partitions; providing control signals to each sub-partition; and providing clock signals to dynamically-selected ones of said plurality of sub-partitions.

In one embodiment, the control signals comprise scan signals that are applied to scan chains in each of the sub-partitions.

In one embodiment, a complete LBIST design is divided into sub-partitions that can be dynamically grouped and controlled by an LBIST power management module in order to achieve a desired power profile of an integrated circuit under test. In this way, a peak or average power profile of the LBIST design can be controlled during LBIST execution.

In one embodiment, clock gating logic modules associated with each sub-partition are used for providing the scan latches (or flip-flops) of scan chains of each sub-partition with a clock signal. Each clock gating logic module receives a clock enable/inhibit signal from the LBIST power management module. A clock gating logic module may thus enable or inhibit a clock signal from reaching a particular sub-partition. Therefore, selected groups of sub-partitions may be rendered either active or inactive during LBIST execution. Different groups of sub-partitions may be run in a round-robin fashion. The invention allows for different portions of the design to be excited selectively (by gating the clocks of some of the scan chains). Consequently only a small portion of the flip-flops are toggled concurrently. Advantageously, this selective toggling of portions of the LBIST design, by grouping of sub-partitions, results in lower power consumption during LBIST execution.

Advantageously, the invention permits toggling to be gradually increased during LBIST execution and in a controlled manner, thereby reducing the power droop encountered with known systems. Furthermore a gradual increase in activity, permitted by the dynamic grouping of sub-partitions under test, prevents failures which, in the known systems, can occur due to low voltage detectors of the integrated circuit under test triggering owing to the presence of local hotspots in the LBIST design.

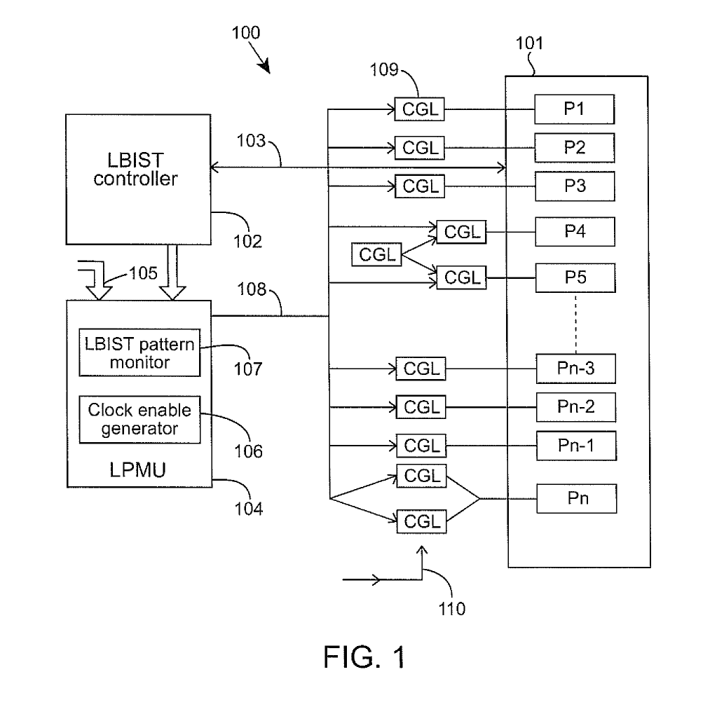

Referring now to FIG. 1, a simplified schematic block diagram of portions of an integrated circuit 100 configured for LBIST testing is shown. The integrated circuit has an LBIST partition 101, which may be one of several partitions in an LBIST domain. The LBIST partition 101 includes a plurality of sub-partitions labelled P1 through Pn. An LBIST controller 102 of conventional design is operably coupled to the partition 101 and supplies control signals including scan in-scan out signals on line 103 to scan chains (not shown) included in each of the sub-partitions P1-Pn. An LBIST power management unit (LPMU) 104 is operably coupled to the LBIST controller 102 and receives inputs on an input line 105. The LPMU 104 includes a clock enable generator 106 and an LBIST pattern monitor 107. Clock enable/inhibit signals on line 108 are supplied to each sub-partition P1-PN by way of an associated clock gating logic module (CGL) 109. One clock gating module is associated with each sub-partition.

Each CGL module 109 receives a clock signal input 110 from an external source (not shown). A CGL module 109 can comprise one or more latches and/or logic gates that may either allow a clock signal to be applied to its associated sub-partition or inhibit the clock signal from reaching its associated sub-partition. Enabling or inhibiting a clock signal for any sub-partition can be controlled by the input on line 105. In some embodiments, a single clock domain may have scan chains in two sub-partitions (P4 and P5 for example) so in order to control the scan chains in sub-partitions P4 and P5 independently, two CGL modules 109 are instantiated. In some embodiments, multiple clock domains may have scan chains in single sub-partitions (Pn for example) so in order to control the scan chains in sub-partition Pn, the same clock enable is sent to both (multiple) CGL modules 109.

In operation, the LPMU 104, based on user inputs, groups sub-partitions P1-Pn dynamically for LBIST execution. In one example, say that the number of sub-partitions is ten and the user desires that 60% of the design is to be made active during testing and a remaining 40% to be inactive. In this case, the LPMU 104, in response to the user input, chooses six out of the ten possible sub-partitions for LBIST execution. For example, a first set of sub-partitions numbered one to six are selected for LBIST testing using a first, predetermined set of patterns monitored by the pattern monitor 107. For a subsequent set of patterns, sub-partitions numbered 2 to 7 are selected. For a further set of patterns, sub-partitions numbered three to eight are selected, and so on. A selected sub-partition is one whose clock input is enabled by the action of the clock enable generator 106 together with an associated CGL module 109. All other sub-partitions are inactive during LBIST execution if their clocks are inhibited by the action of their associated CGL module 109.

The invention has certain advantages. By gating (i.e. inhibiting) the clock signals to the sub-partitions, toggling of an the entire integrated circuit can be controlled. This saves the overall energy consumption during LBIST execution and also, at least to some extent, overcomes the problem of power droop at the start of an LBIST test. Furthermore, the user inputs to the LPMU 104 can be determined ‘on-the-fly’ based on test results. The invention also provides the user with the ability to vary LBIST runtime, start activity, jump activity and pattern count. The inventors have observed that under simulated conditions, power consumed by a scan latch in a scan chain of a sub-partition when data is toggling and its clock is inhibited is less than that consumed by known arrangements where data is held constant and the clock is toggling. The invention also reduces or minimizes power consumption during unloaded conditions as the clocks of the individual scan chains are independently gated.

In another example of operation, a complete LBIST test is divided into two parts. A ‘start activity’ can be made comparatively low in order to compensate for a low power management control module response time. Once the LPMU 104 has reached a certain, substantial load value (for example 60%) the number of active sub-partitions can be adjusted in order to gain a maximum saving on total energy consumption. For example typically, 10 μs is required for the power management control module to reach 80% of its full load value. With an LBIST frequency of 50 MHz, ten test patterns can be run during this time. So for the first 10 patterns, a sub-partition activity level of 10% can be set and then increased in steps of 10% per every two patterns in order to reach a certain activity mark. The total duration time available for an LBIST run is generally known at the start. Hence knowing this total duration time and the shift frequency, the number of LBIST patterns which can be used can be calculated.

An example of an analysis for best energy profile can be performed as follows. After the initial ramp up, assume initial activity is 60% and incremental activity is 20% and that during the 60% activity time the LBIST runs for time t1, during the 80% for a time t2 and the total runtime is T (which is known up-front). An energy equation may be written:

E=0.6t1+(0.8t2−t1)+1(T−t1−t2)

Taking a simplified case where t2 equals t1 and t1 equals t;

E=T−0.6t

It can be inferred from the above expression for an energy value E, that the longer t is, the lesser will be the energy, E. If a desired pattern coverage is met in a pattern count, which is less than P, then more LBIST patterns can be afforded within the self-test runtime T. Consequently, the LBIST design can be run at even lower activity numbers, so significantly reducing energy consumption. As pattern count increases during the LBIST run, the initial set of patterns becomes redundant because statistically, each pattern has the capability to target the same number of faults. Furthermore, as only a relatively small portion of the LBIST design is toggled concurrently at start-up, there is no major detrimental effect on coverage or pattern count.

For example, when partitions of an LBIST design are toggled with 60% of their sub-partitions being active for the first time period, followed by 80% for a second time period and finally reaching 100%, an energy saving of between eight and ten percent is observed compared with known systems.

Further benefits in energy-saving may be realized by taking into account a relative weightage (or weighting) of the sub-partitions. In one example, sub-partitions can be run in a round-robin fashion depending on the relative weightage of each sub-partition. A weightage of a sub-partition (W) equals the summation of the fan out of all its flip-flops in the scan chain. The higher the weightage, then the higher is the coverage impact, statistically speaking. In one example, during LBIST execution, the LPMU 104 is arranged to increase the run duration for those sub-partitions with greater weightage in order to increase test coverage. The weightings of sub-partitions can be pre-programmed into the LPMU 104.

As an example, suppose a partition 101 comprises ten sub-partitions with weightages W1-W10 and the current activity is 60%. That is, the first six sub-partitions are running an LBIST test and the remaining four are inactive. A run time for execution of the first six sub-partitions can be written:

((sum[W1−W6])/(sum[W1−W10]))*total_run_time

Similarly when sub-partitions two to seven are running, run time can be written as:

((sum[W2−W7])/(sum[W1−W10]))*total_run_time

The above method assures that partitions with higher coverage will have greater LBIST execution time. Further, suppose that ‘m’ out of ‘n’ sub-partitions are running simultaneously, then a runtime for LBIST execution can be written as:

((sum[W1−Wm]/(sum[W1−Wn]))*total_run_time

The connections as discussed herein may be any type of connection suitable to transfer signals from or to the respective nodes, units or modules, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice-versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Those skilled in the art will recognize that the boundaries between logic blocks and modules are merely illustrative and that alternative embodiments may merge logic blocks or circuit elements or impose an alternate decomposition of functionality upon various logic blocks, modules or circuit elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediate components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Further, the entire functionality of the modules shown in FIG. 1 may be implemented in an integrated circuit. Such an integrated circuit may be a package containing one or more dies. Alternatively, the examples may be implemented as any number of separate integrated circuits or separate devices interconnected with each other in a suitable manner. For example, an integrated circuit device may comprise one or more dies in a single package with electronic components provided on the dies that form the modules and which are connectable to other components outside the package through suitable connections such as pins of the package and bondwires between the pins and the dies.

The examples, or portions thereof, may implemented as soft or code representations of physical circuitry or of logical representations convertible into physical circuitry, such as in a hardware description language of any appropriate type. Further, the invention is not limited to physical devices or units implemented in non-programmable hardware but can also be applied in programmable devices or units able to perform the desired device functions by operating in accordance with suitable program code, such as mainframes, minicomputers, servers, workstations, personal computers, notepads, personal digital assistants, electronic games, automotive and other embedded systems, cell phones and various other wireless devices, commonly denoted in this application as ‘computer systems.

However, other modifications, variations and alternatives are also possible. The specifications and drawings are, accordingly, to be regarded in an illustrative rather than in a restrictive sense.

Descriptions of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. An integrated circuit, comprising:
a Logic built-in self-test (LBIST) partition having a plurality of sub-partitions;
a controller, coupled to the LBIST partition, for providing control signals, wherein each of the sub-partitions receives the control signals; and
a power management module, coupled to to the controller, for generating a clock enable/inhibit signal and enabling clock signals to be provided to selected ones of the plurality of sub-partitions.

2. The integrated circuit of claim 1, wherein the control signals comprise scan signals and the sub-partitions each include scan chains for receiving the scan signals and a clock signal.

3. The integrated circuit of claim 1, wherein the selected ones of the plurality of sub-partitions are dynamically selected.

4. The integrated circuit of claim 1, further comprising:
a plurality of clock gating logic modules, each of the clock gating logic modules being associated with a respective one of the sub-partitions, for receiving the clock enable/inhibit signal from the power management module and a clock signal, and enabling or inhibiting the clock signal from reaching an associated sub-partition depending on the received enable/inhibit signal.

5. An integrated circuit, comprising:
a Logic built-in self-test (LBIST) partition having a plurality of LBIST sub-partitions;
an LBIST controller coupled to the LBIST partition for providing control signals, wherein each of the sub-partitions receives the control signals;
an LBIST power management module coupled to the LBIST controller for providing a clock enable/inhibit signal for enabling clock signals provided to selected ones of the sub-partitions; and
a plurality of clock gating logic modules, each of the clock gating logic modules being associated with a respective one of the sub-partitions, for receiving the clock enable/inhibit signal from the LBIST power management module and a clock signal, and enabling or inhibiting the clock signal from reaching a sub-partition depending on the received enable/inhibit signal.

6. A method for testing an LBIST partition of an integrated circuit, the method comprising:
dividing an LBIST partition into a plurality of LBIST sub-partitions;
providing control signals to each sub-partition; and
providing clock signals to selected ones of the plurality of sub-partitions.
